(19) United States
(12) Patent Application Publication
(10) Pub. No.: US 2025/0218989 A1
(43) Pub. Date: Jul. 3, 2025

(54) Electronic Component

(71) Applicant: INTELPRO INC., Hsinchu County (TW)

(72) Inventors: Lung-Kun Yu, New Taipei City (TW); Huai-Yi Hsu, New Taipei City (TW); Yu-Kuang Lien, Hsinchu county (TW); Shang-Ta Tsai, Hsinchu City (TW); Wen-Yuan Hsiao, Hsinchu County (TW); Yen-Chih Chen, Hsinchu County (TW)

(73) Assignee: INTELPRO INC., Hsinchu County (TW)

(21) Appl. No.: 19/002,752

(22) Filed: Dec. 27, 2024

(30) Foreign Application Priority Data
Dec. 28, 2023 (TW) 112151309

(51) Int. Cl. H01L 23/00; H01L 23/29; H01L 23/31; H01L 23/495; H01L 23/528; H01L 25/18

(52) U.S. Cl. CPC H01L 24/08; H01L 23/49548; H01L 23/5283; H01L 23/5286; H01L 24/06; H01L 25/18; H01L 23/293; H01L 23/3121; H01L 24/05; H01L 24/48; H01L 2224/05013; H01L 2224/05014; H01L 2224/06051; H01L 2224/06135; H01L 2224/08265; H01L 2224/48091; H01L 2224/48225; H01L 2924/1205; H01L 2924/1206; H01L 2924/1207

(57) ABSTRACT

An electronic component includes an integrated circuit die, having an upper surface including a plurality of bonding pads, wherein the plurality of bonding pads are electrically connected to a circuit of the integrated circuit die; and at least one passive component, electrically connected to the plurality of bonding pads by soldering.

### BACKGROUND OF THE INVENTION

### 1. Field of the Invention

The present invention relates to an electronic component, and more particularly to an electronic component that can reduce circuit board area while effectively maintaining electrical characteristics, enhancing internal power integrity, high-speed signal integrity, and resistance to radio frequency interference.

### 2. Description of the Prior Art

With advancing technology, electronic products such as wearable devices, handheld devices, Internet of Things (IoT) devices, artificial intelligence devices, and wireless communication devices are becoming increasingly multifunctional, driving substantial demand for integrated circuits (ICs). However, users increasingly demand thinner and more portable devices. This creates particular challenges as many applications require ICs with strict line width/spacing density requirements while remaining cost-effective. Additionally, there is growing demand for homogeneous and heterogeneous integration of chips in end products. Therefore, reducing the size of electronic devices has become critically important. A key factor in this is reducing circuit board area, as circuit boards are among the most space-consuming components in electronic devices. Reducing circuit board area not only saves material costs but also improves the performance and reliability of electronic devices, for example by reducing signal transmission delays and interference. Consequently, minimizing circuit board area has become a crucial objective in electronic device design and manufacturing.

### SUMMARY OF THE INVENTION

Therefore, the present invention is to provide an electronic component, capable of enhancing electrical characteristics of integrated circuit packaging.

An embodiment of the present invention discloses an electronic component, which comprises an integrated circuit die, having an upper surface comprising a plurality of bonding pads, wherein the plurality of bonding pads are electrically connected to a circuit of the integrated circuit die; and at least one passive component, electrically connected to the plurality of bonding pads by soldering.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 illustrates a schematic diagram of an electronic component 10 according to an embodiment of the present invention.

FIG. 2A and FIG. 2B illustrates schematic diagrams of a structure of a passive component shown in FIG. 1.

FIG. 3 illustrates a schematic diagram of an embodiment of an integrated circuit die shown in FIG. 1.

FIG. 4 illustrates a schematic diagram of an electronic device according to an embodiment of the present invention.

### DETAILED DESCRIPTION

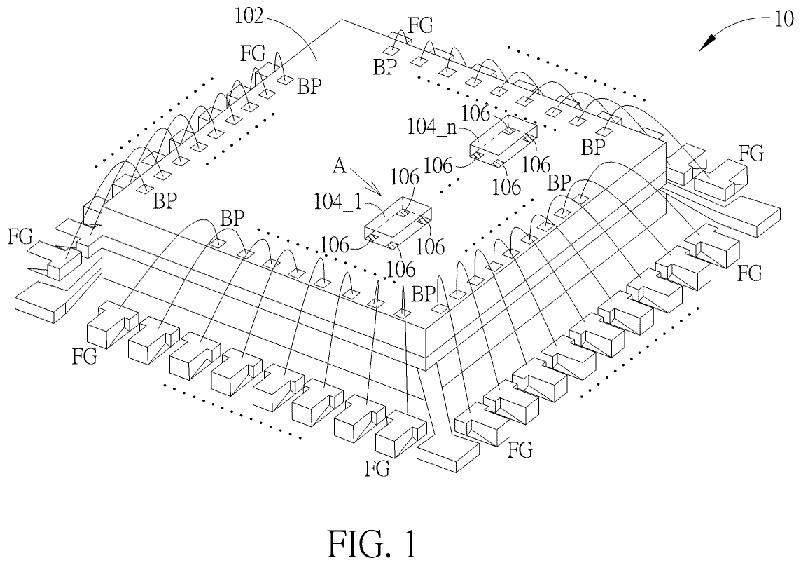

Please refer to FIG. 1, which illustrates a schematic diagram of an electronic component 10 according to an embodiment of the present invention. The electronic component 10 may be used in electronic products such as wearable devices, handheld devices, IoT devices, AI devices, and wireless communication devices, and may integrate passive components to reduce the required circuit board area of the electronic products. Additionally, when the electronic component 10 implements the power supply network for electronic products, it exhibits excellent electrical characteristics that enhance internal power integrity (PI), high-speed signal integrity (SI), and resistance to radio frequency interference (RFI). Specifically, the electronic component 10 includes an integrated circuit die 102 and passive components 104_1 to 104_n. The upper surface of the integrated circuit die 102 features a plurality of input/output bumps BP, which are electrically connected to a plurality of leads FG through wire bonding, a structure well-known in the field. Furthermore, a plurality of bonding pads 106 are formed on the upper surface of the integrated circuit die 102 to electrically connect with the passive components 104_1 to 104_n through soldering. In other words, the passive components 104_1 to 104_n are directly placed on the upper surface of the integrated circuit die 102 and electrically connected to its internal circuit through the bonding pads 106. In this configuration, the passive components 104_1 to 104_n do not occupy circuit board space, thereby reducing board area, and do not require traces or wire bonding for connection to the integrated circuit die 102, thereby effectively enhancing electrical characteristics and improving internal power integrity, high-speed signal integrity, and RFI resistance.

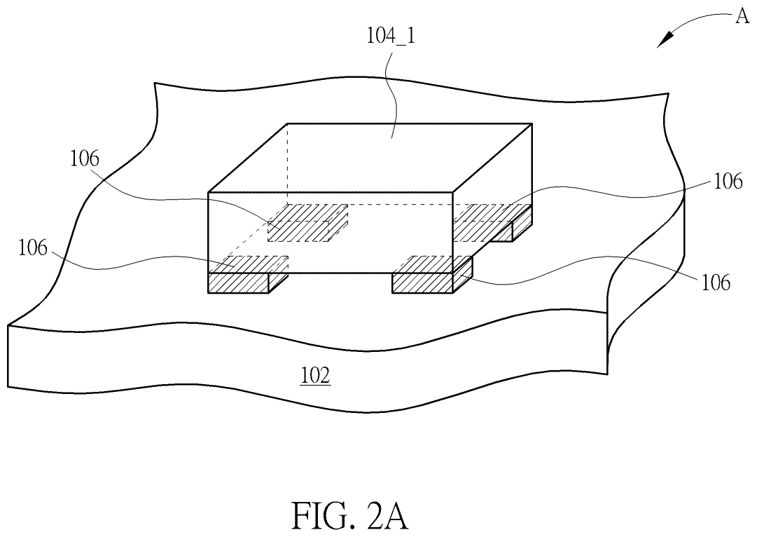

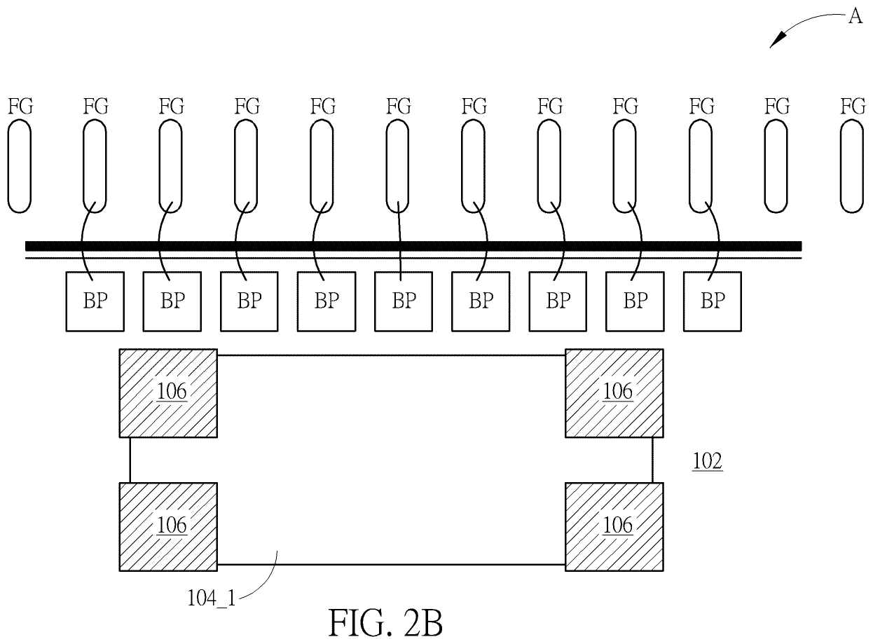

In short, in the electronic component 10, the passive components 104_1 to 104_n are not placed on the circuit board and connected to the integrated circuit die 102 through board traces or additional wire bonding. Instead, the passive components 104_1 to 104 n are directly mounted on the upper surface of the integrated circuit die 102 through the bonding pads 106. This creates an extremely short electrical connection path between the passive components 104_1 to 104_n and the integrated circuit die 102 through the bonding pads 106, facilitating electrical signal transmission. Different passive component values can also enhance interference and noise resistance. Specifically, please refer to FIG. 2A and FIG. 2B, which show enlarged partial and top views of an area A from FIG. 1, illustrating the structure of the passive component 104_1 relative to the integrated circuit die 102. As shown, the passive component 104_1 is electrically connected to the integrated circuit die 102 through four bonding pads 106. Since the bonding pads 106 are formed on the upper surface of the integrated circuit die 102, the passive component 104_1 is mounted directly above it with an extremely short connection path to the internal circuit, eliminating circuit board space requirements while ensuring electrical performance and enhancing power integrity, signal integrity, and RFI resistance.

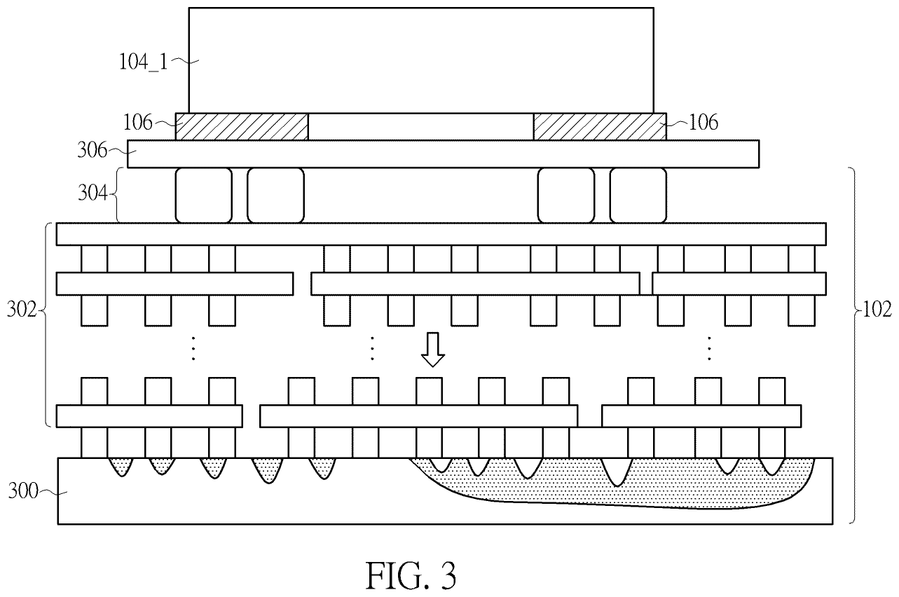

It should be noted that FIG. 2A and FIG. 2B show the structure related to the passive component 104_1; other passive components 104_2 to 104_n have similar structures, which will not be detailed here. Moreover, the electronic component 10 represents one embodiment of the present invention, and those skilled in the art can make various modifications without limitation. For example, FIG. 3 illustrates a schematic diagram of an embodiment of the integrated circuit die 102. In this example, where the electronic component 10 implements a power supply chip, the integrated circuit die 102 includes a substrate 300, at least one metal layer 302, a power and ground layer 304, and a redistribution layer 306. The metal layer 302 is placed on the substrate 300 to form the circuit. The power and ground layer 304 is placed above the metal layer 302 to provide power and ground to the internal circuit. The redistribution layer 306 is placed between the power and ground layer 304 and the bonding pads 106 to connect them. Notably, the redistribution layer 306 uses wafer-level metallization and bump processes to modify the contact positions of the integrated circuit die 102, allowing it to be used in different component modules—in this case, accommodating the placement of the passive component 104_1. The wafer-level metallization process involves applying a protective layer on the passive component 104_1, defining new conductor patterns through photolithography, and creating new metal conductors using electroplating and etching techniques to connect original circuit points with the new bonding pads 106, achieving circuit redistribution. However, this is not limiting; any method that can adjust the contact positions of the integrated circuit die 102 to accommodate required passive component placement is applicable to the present invention.

Furthermore, the passive components 104_1 to 104_n can be capacitors, inductors, resistors, or other passive components, preferably conforming to 01005 specifications (approximately 0.4 mm×0.2 mm in length×width), though this is not limiting. In FIG. 1, the passive components 104_1 to 104_n (or bonding pads 106) are placed near the edge of the integrated circuit die 102, but they could also be placed in the center or any appropriate position. Moreover, those skilled in the art can adjust the quantity n of the passive components 104_1 to 104_n according to system requirements.

Similarly, there are no limitations on the implementation methods, processes, materials, quantities, etc., of the integrated circuit die 102, the bonding pads 106, the input/output bumps BP, and the leads FG. Those skilled in the art can make appropriate adjustments according to system requirements.

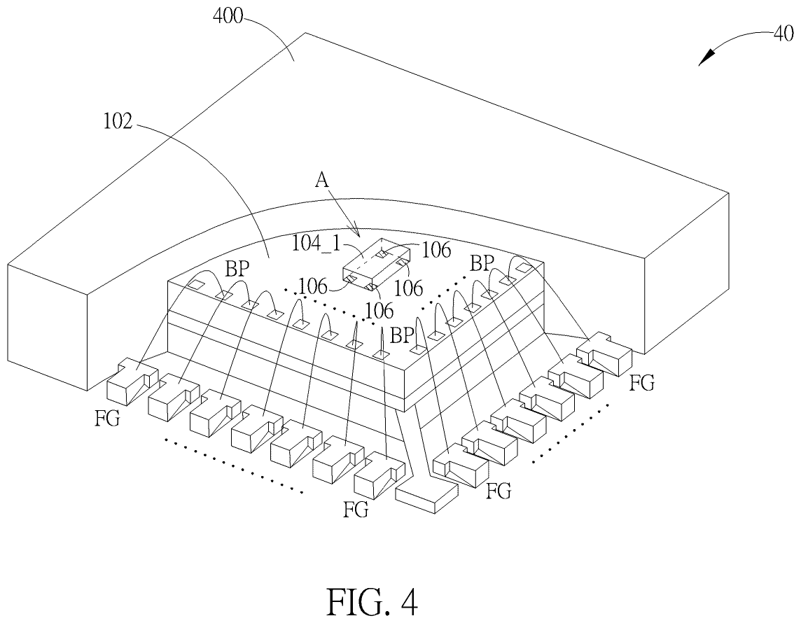

On the other hand, FIG. 1 shows the basic structure of the electronic component 10. In practical applications, various packaging procedures can be employed to protect the electronic component 10. In one embodiment, the electronic component 10 can utilize Quad Flat Non-leaded (QFN) or Ball Grid Array (BGA) packaging. Please refer to FIG. 4, which illustrates a schematic diagram of an electronic device 40 according to an embodiment of the present invention. The electronic device 40 protects the electronic component 10 shown in FIG. 1 using QFN packaging, specifically employing a plastic encapsulation 400 to protect the electronic component 10. As shown in FIG. 4, the QFN packaging exposes the leads FG beneath the encapsulation compound, further reducing the required circuit board area. Combined with the passive components 104_1 to 104_n being directly mounted on the upper surface of the integrated circuit die 102, this effectively minimizes the required circuit board area. It should be noted that when using QFN packaging for the electronic component 10, those skilled in the art can appropriately adjust the QFN packaging process to accommodate the placement of the passive components 104_1 to 104_n. For example, in one embodiment, space for the passive components 104_1 to 104_n can be reserved before packaging, allowing for subsequent soldering of these components. In another embodiment, holes can be created in the plastic encapsulation 400 after packaging to accommodate the passive components 104_1 to 104_n. However, regardless of the packaging method, any approach that can protect the electronic component 10 while allowing appropriate placement of the passive components 104_1 to 104_n on the integrated circuit die 102 falls within the scope of the present invention.

In conventional technology, passive components are placed on the circuit board and electrically connected to the integrated circuit chip through board traces. In this structure, passive components not only occupy circuit board area, but the design factors of traces such as length, width, extension method, and position also affect interference resistance and electrical characteristics. In contrast, in the present invention, passive components are not placed on the circuit board and connected to the integrated circuit die through board traces, but are directly mounted on the integrated circuit die. Therefore, the passive components in the embodiment of the present invention do not require circuit board space, reducing board area, while the extremely short connection path between the passive components and the integrated circuit die effectively maintains electrical characteristics, thereby enhancing internal power integrity, high-speed signal integrity, and radio frequency interference resistance.

In conclusion, by mounting the passive components on the integrated circuit die, the electronic component of the present invention can reduce circuit board area, effectively enhance electrical characteristics, and improve internal power integrity, high-speed signal integrity, and radio frequency interference resistance capabilities.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. An electronic component, comprising:
an integrated circuit die, having an upper surface comprising a plurality of bonding pads, wherein the plurality of bonding pads are electrically connected to a circuit of the integrated circuit die; and
at least one passive component, electrically connected to the plurality of bonding pads by soldering.

2. The electronic component of claim 1, wherein the integrated circuit die comprises:
a substrate;
at least one metal layer, disposed on the substrate, for forming the circuit;
a power and ground layer, disposed on the at least one metal layer, for providing power and ground to the circuit; and
a redistribution layer, disposed between the power and ground layer and the plurality of bonding pads, for connecting the power and ground layer to the plurality of bonding pads.

3. The electronic component of claim 1, wherein the at least one passive component is selected from capacitors, inductors, and resistors.

4. The electronic component of claim 1, wherein the at least one passive component conforms to 01005 specifications.

5. The electronic component of claim 1, being protected by a Quad Flat Non-leaded (QFN) package.

6. The electronic component of claim 5, wherein the Quad Flat Non-leaded package has at least one hole corresponding to at least one connector.

7. The electronic component of claim 1, wherein the plurality of bonding pads are formed at an edge of the integrated circuit die.

8. The electronic component of claim 1, being used for power supply of an electronic device.
